(19) United States
(12) Patent Application Publication
(10) Pub. No.: US 2024/0194554 A1
(43) Pub. Date: Jun. 13, 2024

(54) POWER MODULE

(71) Applicant: Delta Electronics, Inc., Taoyuan City (TW)

(72) Inventors: Jen-Hsien Wong, Taoyuan City (TW); Han-Lin Wu, Taoyuan City (TW); Chun-Liang Chiang, Taoyuan City (TW); Tai-Kuang Lee, Taoyuan City (TW)

(21) Appl. No.: 18/138,506

(22) Filed: Apr. 24, 2023

(30) Foreign Application Priority Data
Dec. 13, 2022 (CN) 202211602836.X

(51) Int. Cl. H01L 23/31; H01L 21/56; H01L 23/00; H01L 23/495; H01L 25/07

(52) U.S. Cl. CPC H01L 23/3142; H01L 21/565; H01L 23/49562; H01L 24/48; H01L 25/072; H01L 2224/48137; H01L 2924/13091; H01L 2924/186

(57) ABSTRACT

The present disclosure provides a power module including a substrate, a plurality of semiconductor devices, a plurality of pins and a encapsulation material. The semiconductor devices are disposed on the first metal surface of the substrate. The extending direction of each pin is perpendicular to the bottom side of the first metal surface. Each of pins extends out of the encapsulation material along an identical direction. The plurality of pins include a positive and a negative voltage pins. An end of the positive voltage pin is attached to the middle position of the first side of the first metal surface. An end of the negative voltage pin is attached to the middle position of the second side of the first metal surface. The first and second sides are spatially opposite to each other, and the first and second sides are connected to the bottom side of the first metal surface.

### CROSS-REFERENCE TO RELATED APPLICATION

This application claims priority to China Patent Application No. 202211602836.X, filed on Dec. 13, 2022, the entire contents of which are incorporated herein by reference for all purposes.

### FIELD OF THE INVENTION

The present disclosure relates to a power module, and more particularly to a power module with multiple semiconductor devices disposed on one substrate.

### BACKGROUND OF THE INVENTION

In the conventional charging pile equipment, the power conversion unit needs to use multiple discrete components with TO247 structure. Each discrete component with TO247 structure has a MOSFET chip, and the size and power density of the discrete component are fixed.

Since the size and power density of each discrete component are fixed, in order to satisfy the rising power requirements of equipment, more discrete components must be used simultaneously as compared to the conventional equipment with lower power requirements to meet high power requirements. However, the increased number of discrete components would cause the volume of the equipment to increase. In addition, due to the increased amount of the electronic components, the heat dissipation inside the equipment is more difficult.

Therefore, there is a need of providing a power module to obviate the drawbacks encountered from the prior arts.

### SUMMARY OF THE INVENTION

It is an object of the present disclosure to provide a power module with a plurality of semiconductor devices disposed on one substrate. Therefore, the multiple conventional discrete components are replaced by one power module, thereby reducing the volume and increasing the power density. In addition, in the present disclosure, the positive voltage pin and the negative voltage pin are attached to the middle position of the side of the metal surface, thereby increasing the structural stability of the power module and extending the service life.

In accordance with an aspect of the present disclosure, there is provided a power module. The power module includes a substrate, a plurality of semiconductor devices, a plurality of pins and a encapsulation material. The substrate includes a first metal surface, and the plurality of semiconductor devices are disposed on the first metal surface. The extending direction of each of the plurality of pins is perpendicular to the bottom side of the first metal surface. The encapsulation material is configured to seal the first metal surface and the plurality of semiconductor devices and to seal each pin partially. Each of the plurality of pins extends out of the encapsulation material along an identical direction. The plurality of pins include a positive voltage pin and a negative voltage pin. An end of the positive voltage pin is attached to the middle position of the first side of the first metal surface. An end of the negative voltage pin is attached to the middle position of the second side of the first metal surface. The first and second sides are spatially opposite to each other, and the first and second sides are connected to the bottom side of the first metal surface.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a power module according to an embodiment of the present disclosure;

FIG. 2 is a schematic perspective view of a part of the power module in FIG. 1;

FIG. 3 is a top view of the power module in FIG. 2;

FIG. 4 is a schematic current flow diagram of the power module in FIG. 3 receiving the power supply current;

FIG. 5 is a schematic current flow diagram of the power module receiving the power supply current according to another embodiment of the present disclosure;

FIG. 6 is a schematic current flow diagram of the power module receiving the power supply current according to another embodiment of the present disclosure; and

FIG. 7 is a schematic cross-sectional view of the power module in FIG. 1.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

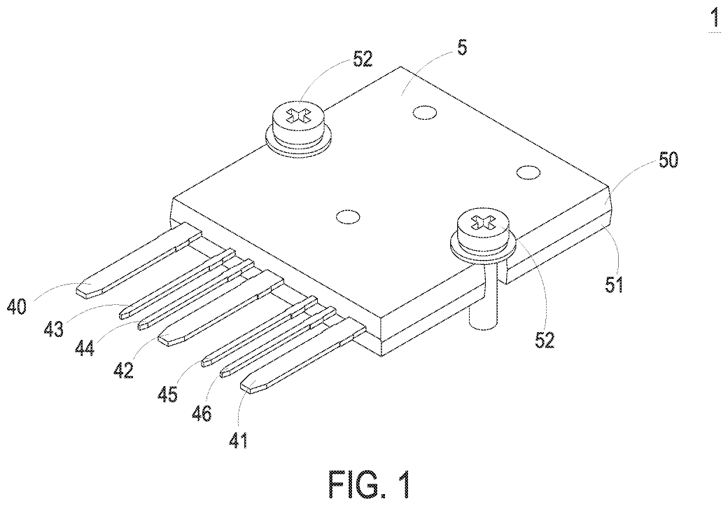

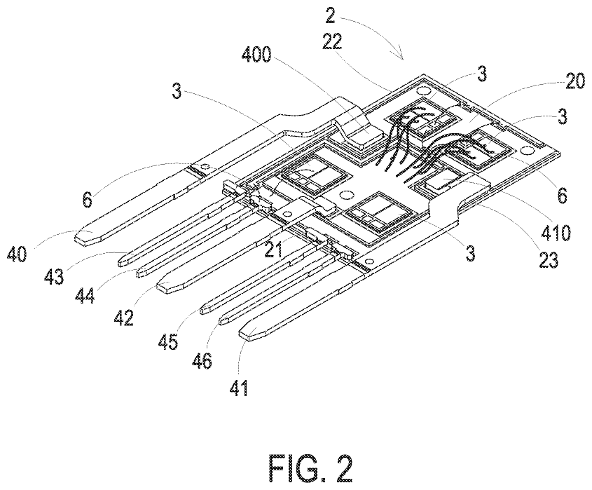

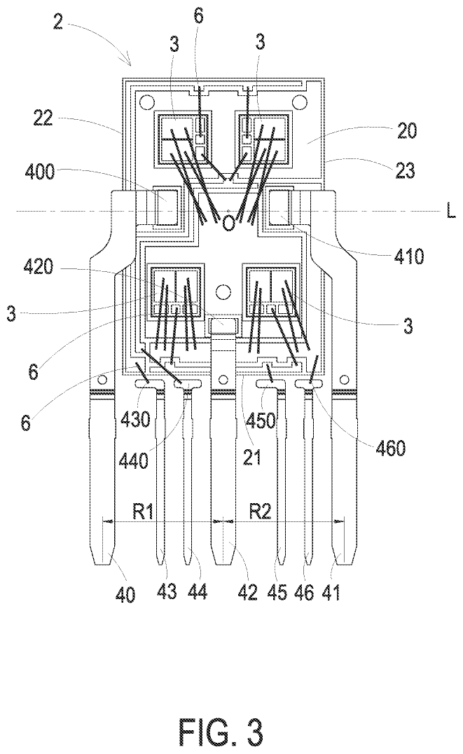

FIG. 1 is a schematic perspective view illustrating a power module according to an embodiment of the present disclosure. FIG. 2 is a schematic perspective view of a part of the power module in FIG. 1. FIG. 3 is a top view of the power module in FIG. 2. As shown in FIGS. 1, 2 and 3, the power module 1 includes a substrate 2, a plurality of semiconductor devices 3, a plurality of pins and a encapsulation material 5. The substrate 2 includes a first metal surface 20, and the plurality of semiconductor devices 3 are disposed on the first metal surface 20. In an embodiment, the amount of the plurality of pins is odd, and the amount of the plurality of pins is greater than or equal to three. The extending direction of each of the plurality of pins is perpendicular to the bottom side 21 of the first metal surface 20. The encapsulation material 5 is configured to seal the first metal surface 20 and the plurality of semiconductor devices 3 and to seal each pin partially. Each of the plurality of pins extends out of the encapsulation material 5 along an identical direction. The plurality of pins include a positive voltage pin 40 and a negative voltage pin 41. An end 400 of the positive voltage pin 40 is attached to the middle position of the first side 22 (for example but not limited to the midpoint of the first side 22) of the first metal surface 20. An end 410 of the negative voltage pin 41 is attached to the middle position of the second side 23 (for example but not limited to the midpoint of the second side 23) of the first metal surface 20. Since the end 400 of the positive voltage pin 40 and the end 410 of the negative voltage pin 41 are attached to the middle positions of the first side 22 and the second side 23 respectively, the structure of the power module 1 is stable when the power module 1 is affected by external force during the assembly process, thereby improving the reliability and service life of the power module 1. The first side 22 and the second side 23 are spatially opposite to each other and are both connected to the bottom side 21 of the first metal surface 20. In the power module 1 of the present disclosure, the plurality of semiconductor devices 3 are disposed on one substrate 2. Accordingly, the multiple conventional discrete components are replaced by one power module 1, thereby reducing the volume and increasing the power density. In addition, the positive voltage pin and the negative voltage pin of the power module 1 are attached to the middle position of the side of the metal surface, thereby increasing the structural stability of the power module 1 and extending the service life.

In an embodiment, the end 400 of the positive voltage pin 40 is disposed between two semiconductor devices 3, and the end 401 of the positive voltage pin 41 is disposed between two semiconductor devices 3. Accordingly, the heat dissipation effect of the power module 1 is improved.

In an embodiment, the amount of the semiconductor devices 3 is even. The power module 1 shown in FIGS. 1, 2 and 3 includes four semiconductor devices 3, and the four semiconductor devices 3 are arranged on the first metal surface 20 to form a matrix. The center O of the matrix and the middle positions of the first side 22 and the second side 23 are spatially located on the same horizontal line L.

In an embodiment, the plurality of pins further includes a phase voltage pin 42 disposed between the positive voltage pin 40 and the negative voltage pin 41. An end 420 of the phase voltage pin 42 is attached to the first metal surface 20, and a position where the end 420 of the phase voltage pin 42 is attached to the first metal surface 20 is closer to the bottom side 21 relative to the horizontal line L. The first distance R1 between the phase voltage pin 42 and the positive voltage pin 40 is equal to the second distance R2 between the phase voltage pin 42 and the negative voltage pin 41.

In an embodiment, the positive voltage pin 40, the negative voltage pin 41 and the phase voltage pin 42 have the same cross-sectional area which is the largest cross-sectional area among the plurality of pins. Therefore, the positive voltage pin 40, the negative voltage pin 41 and the phase voltage pin 42 are able to withstand the power supply current input from outside of the power module 1.

In an embodiment, the plurality of pins further includes a first gate pin 43 and a first source pin 44. The first gate pin 43 and the first source pin 44 are disposed within the first distance R1, namely the first gate pin 43 and the first source pin 44 are located between the phase voltage pin 42 and the positive voltage pin 40. An end 430 of the first gate pin 43 and an end 440 of the first source pin 44 are adjacent to the bottom side 21 of the first metal surface 20 and are electrically connected to the first metal surface 20 through at least one power transmission wire 6. Among the plurality of the power transmission wires 6, part of the power transmission wires 6 are used for signal transmission, and part of the power transmission wires 6 are used for power transmission. In an embodiment, the signal of the power transmission wire 6 is provided by the semiconductor device 3 on the first metal surface 20. The encapsulation material 5 seals the end 430 of the first gate pin 43 and the end 440 of the first source pin 44. It should be noted that only part of the power transmission wires 6 are labeled in the figures for making the figure concise.

In an embodiment, the plurality of pins further includes a second gate pin 45 and a second source pin 46. The second gate pin 45 and the second source pin 46 are disposed within the second distance R2, namely the second gate pin 45 and the second source pin 46 are located between the phase voltage pin 42 and the negative voltage pin 41. An end 450 of the second gate pin 45 and an end 460 of the second source pin 46 are adjacent to the bottom side 21 of the first metal surface 20 and are electrically connected to the first metal surface 20 through at least one power transmission wire 6. In an embodiment, the signal of the power transmission wire 6 is provided by the semiconductor device 3 on the first metal surface 20. The encapsulation material 5 seals the end 450 of the second gate pin 45 and the end 460 of the first source pin 46.

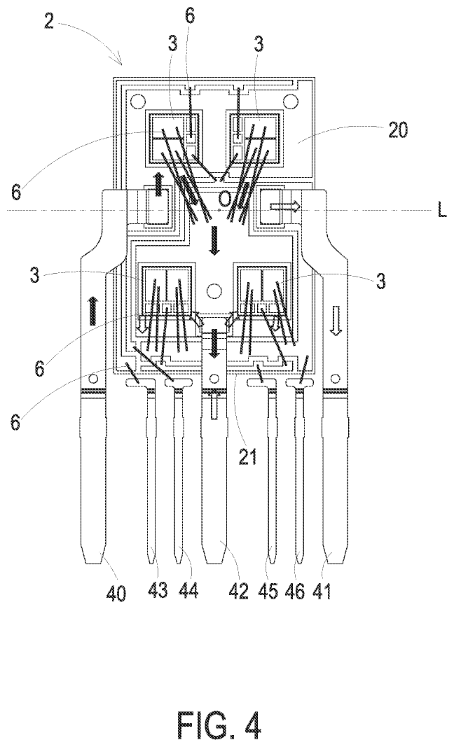

Please refer to FIG. 4. FIG. 4 is a schematic current flow diagram of the power module in FIG. 3 receiving the power supply current. Each semiconductor device 3 is electrically connected to the first metal surface 20 through at least one power transmission wire 6. In FIG. 4, the direction of the solid arrow represents the direction of the power supply current flowing into and out of the power module 1 through the positive voltage pin 40 and the phase voltage pin 42 respectively. When the positive voltage pin 40 receives the power supply current, the power supply current flows through the semiconductor device 3 which is higher than the horizontal line L (i.e., the semiconductor device 3 and the bottom side 21 are at different sides of the horizontal line L) via the first metal surface 20 and at least one power transmission wire 6, and the power supply current flows out of the power module 1 through the phase voltage pin 42.

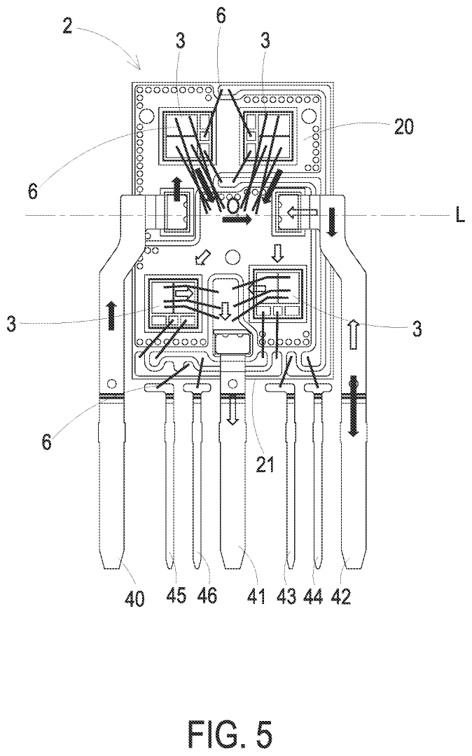

The position of the pins of the power module of the present disclosure is not limited to that of the power module 1 shown in FIGS. 3 and 4. Please refer to FIG. 5, the difference between the power module 1 shown in FIG. 5 and the power module 1 shown in FIG. 4 is the position of the pins. As the embodiment shown in FIG. 5, the negative voltage pin 41 is disposed between the phase voltage pin 42 and the positive voltage pin 40, the second gate pin 45 and the second source pin 46 are disposed between the positive voltage pin 40 and the negative voltage pin 41, and the first gate pin 43 and the first source pin 44 are disposed between the negative voltage pin 41 and the phase voltage pin 42. In FIG. 5, the direction of the solid arrow represents the direction of the power supply current flowing into and out of the power module 1 through the positive voltage pin 40 and the phase voltage pin 42 respectively. In the embodiment shown in FIG. 5, after the power supply current flows through the semiconductor device 3 which is higher than the horizontal line L, the power supply current flows out of the power module 1 through the phase voltage pin 42.

In an embodiment, the power supply current may flow into the power module 1 through the phase voltage pin 42, and the power supply current flows through the semiconductor device 3 which is lower than the horizontal line L (i.e., the semiconductor device 3 and the bottom side 21 are at the same side of the horizontal line L). The embodiment of the power supply current flowing into the power module 1 through the phase voltage pin 42 is shown in FIGS. 4 and 5 and is exemplified as follow.

Please refer to FIGS. 4 and 5, in FIGS. 4 and 5, the direction of the hollow arrow represents the direction of the power supply current flowing into and out of the power module 1 through the phase voltage pin 42 and the negative voltage pin 41 respectively. In the embodiment shown in FIGS. 4 and 5, when the phase voltage pin 42 receives the power supply current, the power supply current flows through the semiconductor device 3 which is lower than the horizontal line L via the first metal surface 20 and at least one power transmission wire 6, and the power supply current flows out of the power module 1 through the negative voltage pin 41.

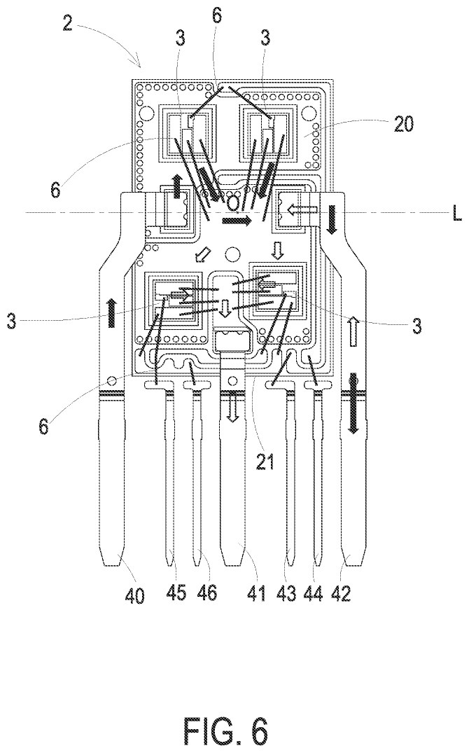

The connection way of the power transmission wires 6 on the first metal surface 20 of the power module of the present disclosure is not limited to that of the power module 1 shown in FIGS. 3, 4 and 5. Please refer to FIG. 6, the difference between the power module 1 shown in FIG. 6 and the power module 1 shown in FIGS. 3, 4 and 5 is the connection way of the power transmission wires 6. In different embodiments, the connection way of the power transmission wires 6 may be different according to the types of semiconductor device and the arrangement relationship between the plurality of pins.

Please refer to FIG. 1 again, in an embodiment, the encapsulation material 5 includes a top sealant 50, a bottom sealant 51 and two fixing components 52 which are detachable. In an embodiment, the top sealant 50 and the bottom sealant 51 are integrally formed, the top sealant 50 and the bottom sealant 51 are injection-molded epoxy, and the top sealant 50 and the bottom sealant 51 form the encapsulation material 5. In an embodiment, the top sealant 50 and the bottom sealant 51 form the encapsulation material 5 and are fixed by two fixing components 52. The fixing component 52 is for example but not limited to a locking screw.

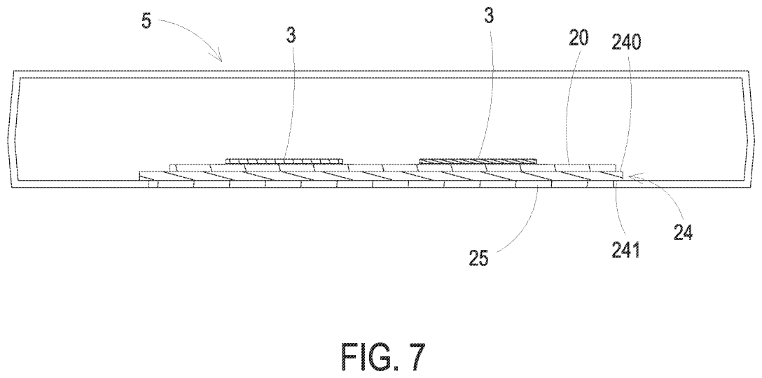

Please refer to FIG. 7, FIG. 7 is a schematic cross-sectional view of the power module in FIG. 1. The substrate 2 of the present disclosure further includes a thermal-conductive insulation plate 24 and a second metal surface 25, and the thermal-conductive insulation plate 24 has a first surface 240 and a second surface 241 opposite to each other. The first metal surface 20 is attached to the first surface 240 of the thermal-conductive insulation plate 24, and the second metal surface 25 is attached to the second surface 241 of the thermal-conductive insulation plate 24. The second metal surface 25 is exposed from the encapsulation material 5. In an embodiment, the encapsulation material 5 is made of a molding compound, and a manufacturing material of the molding compound is epoxy resin.

From the above descriptions, the present disclosure provides a power module with a plurality of semiconductor devices disposed on one substrate. Therefore, the multiple conventional discrete components are replaced by one power module, thereby reducing the volume and increasing the power density. In addition, the positive voltage pin and the negative voltage pin are attached to the middle position of the side of the metal surface, thereby increasing the structural stability of the power module and extending the service life. Since the ends of the positive and negative voltage pins are disposed between two semiconductor devices, the heat dissipation effect of the power module is improved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power module, comprising:
a substrate, comprising a first metal surface;
a plurality of semiconductor devices, disposed on the first metal surface;
a plurality of pins, wherein an extending direction of each of the plurality of pins is perpendicular to a bottom side of the first metal surface; and
an encapsulation material, wherein the encapsulation material is configured to seal the first metal surface and the plurality of semiconductor devices and to seal each pin partially, and each of the plurality of pins extends out of the encapsulation material along an identical direction,
wherein the plurality of pins comprise a positive voltage pin and a negative voltage pin, an end of the positive voltage pin is attached to a middle position of a first side of the first metal surface, an end of the negative voltage pin is attached to a middle position of a second side of the first metal surface, wherein the first side and the second side are spatially opposite to each other, and the first side and the second side are connected to the bottom side of the first metal surface.

2. The power module according to claim 1, wherein the amount of the semiconductor devices is even, and the semiconductor devices are arranged on the first metal surface to form a matrix,
wherein a center of the matrix, the middle positions of the first side and the second side are spatially located on a horizontal line.

3. The power module according to claim 2, wherein the plurality of pins further comprise a phase voltage pin, and the phase voltage pin is disposed between the positive voltage pin and the negative voltage pin, wherein an end of the phase voltage pin is attached to the first metal surface, and a position where the end of the phase voltage pin is attached to the first metal surface is closer to the bottom side relative to the horizontal line.

4. The power module according to claim 3, wherein a first distance between the phase voltage pin and the positive voltage pin is equal to a second distance between the phase voltage pin and the negative voltage pin.

5. The power module according to claim 4, wherein the plurality of pins further comprises a first gate pin and a first source pin, and the first gate pin and the first source pin are disposed within the first distance,
wherein an end of the first gate pin and an end of the first source pin are adjacent to the bottom side of the first metal surface, and the end of the first gate pin and the end of the first source pin are electrically connected to the first metal surface through at least one power transmission wire,
wherein the encapsulation material seals the end of the first gate pin and the end of the first source pin.

6. The power module according to claim 4, wherein the plurality of pins further comprises a second gate pin and a second source pin, and the second gate pin and the second source pin are disposed within the second distance,
wherein an end of the second gate pin and an end of the second source pin are adjacent to the bottom side of the first metal surface, and the end of the second gate pin and the end of the second source pin are electrically connected to the first metal surface through at least one power transmission wire,
wherein the encapsulation material seals the end of the second gate pin and the end of the second source pin.

7. The power module according to claim 3, wherein each of the plurality of semiconductor devices is electrically connected to the first metal surface through at least one power transmission wire respectively,
when the positive voltage pin receives a power supply current, the power supply current flows through the semiconductor device which is higher than the horizontal line via the first metal surface and the at least one power transmission wire.

8. The power module according to claim 7, wherein after the power supply current flows through the semiconductor device which is higher than the horizontal line, the power supply current flows out of the power module through the phase voltage pin.

9. The power module according to claim 7, wherein after the power supply current flows through the semiconductor device which is higher than the horizontal line, the power supply current flows out of the power module through the negative voltage pin.

10. The power module according to claim 7, wherein when the negative voltage pin receives the power supply current, the power supply current flows through the semiconductor device which is lower than the horizontal line via the first metal surface and the at least one power transmission wire,
wherein after the power supply current flows through the semiconductor device which is lower than the horizontal line, the power supply current flows out of the power module through the phase voltage pin.

11. The power module according to claim 7, wherein when the phase voltage pin receives the power supply current, the power supply current flows through the semiconductor device which is lower than the horizontal line via the first metal surface and the at least one power transmission wire,
wherein after the power supply current flows through the semiconductor device which is lower than the horizontal line, the power supply current flows out of the power module through the negative voltage pin.

12. The power module according to claim 3, wherein the plurality of pins have a cross-sectional area, and the positive voltage pin, the negative voltage pin and the phase voltage pin have the largest cross-sectional area among the plurality of pins.

13. The power module according to claim 1, wherein the amount of the plurality of pins is odd, and the amount of the plurality of pins is greater than or equal to three.

14. The power module according to claim 1, wherein the substrate further comprises a thermal-conductive insulation plate and a second metal surface, wherein the first metal surface is attached to a first surface of the thermal-conductive insulation plate, and the second metal surface is attached to a second surface of the thermal-conductive insulation plate, the first surface and the second surface are opposite to each other, and the second metal surface is exposed from the encapsulation material.

15. The power module according to claim 1, wherein the encapsulation material is made of a molding compound, and a manufacturing material of the molding compound is epoxy resin.
